(19) United States
(12) Patent Application Publication
(10) Pub. No.: US 2016/0097821 A1
(43) Pub. Date: Apr. 7, 2016

(54) METHOD FOR MONITORING THE STATE OF A BATTERY IN A MOTOR VEHICLE

(71) Applicant: FORD GLOBAL TECHNOLOGIES, LLC, Dearborn, MI (US)

(72) Inventors: Mark EIFERT, Frankfurt am Main (DE); Eckhard KARDEN, Aachen (DE)

(21) Appl. No.: 14/873,009

(22) Filed: Oct. 1, 2015

(30) Foreign Application Priority Data
Oct. 6, 2014 (DE) 102014220153.5

(51) Int. Cl. G01R 31/36

(52) U.S. Cl. CPC G01R 31/3679; G01R 31/3606; G01R 31/3648

(57) ABSTRACT

This disclosure relates to a method for monitoring the state of a battery of a motor vehicle, with which method internal corrosion in the battery can be identified. In this case, the water loss from the battery is estimated by means of a model, and an evaluation unit generates an alarm signal if the estimated water loss exceeds a defined limit value. The water loss model provides, in particular, that the z-curve, which is used in the charging strategy of the battery, and the battery temperature are used, and the mass flow of the water loss on account of gas development is determined as a function of the used z-curve and the battery temperature from a correlation, which is stored in the evaluation unit, at least between the mass flow of the water loss on account of gas development, a z-curve of the charging strategy and the battery temperature.

### CROSS-REFERENCE TO RELATED APPLICATION

This application claims foreign priority benefits under 35 U.S.C. §119(a)-(d) to DE 10 2014 220 153.5, filed Oct. 6, 2014, which is hereby incorporated by reference in its entirety.

### TECHNICAL FIELD

The disclosure relates to a method for monitoring the state of a battery of a motor vehicle, with which method internal corrosion in the battery is identified.

### BACKGROUND

The monitored battery is, for example, a starter battery. The starter battery of a motor vehicle is a rechargeable battery which supplies the electric current for the starter of an internal combustion engine. The battery of an electric vehicle which serves to drive the vehicle is, by contrast, called the traction battery. In addition, electric vehicles or hybrid vehicles can also have a starter battery. The batteries used can be, for example, rechargeable lead-acid batteries which, however, are also called lead-acid batteries in the text which follows.

As a lead-acid battery ages, this can be accompanied by phenomena such as internal corrosion and a high internal resistance. On account of the high internal resistance and loss of capacitance, said batteries are then no longer able, for example, to provide energy at a sufficient voltage to start the vehicle. In addition, electrical loads which draw more current than the generator or the DC/DC converter of the vehicle is designed to supply cause voltage transients at the battery connections during the discharging operation, this possibly having an adverse effect on the electrical functionality of these or other loads. By way of example, the transients can cause controllers in the vehicle to be shut down and restarted if their low-voltage operating limits are breached. As such, the state of the battery should be monitored, this being possible on the basis of various parameters.

If the electrolyte level falls below the plates, the capacitance likewise drops and the internal resistance increases. The resulting fault modes are identical to those which occur due to corrosion and can be summed up as impairment of electrical functionality during starting and high current transients. The internal corrosion in the battery and gas development play a particular role here. On account of relationships between the charging voltage, the temperature, a gas reaction and the formation of corrosion, the internal corrosion exhibits a high level of correlation with the water loss from the battery. When a high level of water loss is detected, there is a high probability of corrosion being present.

### SUMMARY

It should be noted that the features specified individually in the claims may be combined with one another in any desired technologically meaningful way and disclose further embodiments of the invention. The description, in particular in conjunction with the figures, characterizes and specifies the invention further.

Internal corrosion in the battery can be identified using the method for monitoring the state of a battery of a motor vehicle. In this case, it is provided that the water loss from the battery is estimated by means of a model, and an evaluation unit generates an alarm signal if the estimated water loss exceeds a defined limit value.

An example embodiment therefore comprises an algorithm which predicts the water loss in the battery by means of a water loss model, wherein a water loss above a defined limit value suggests internal corrosion in the battery. However, the water loss does not have to be measured in a complicated manner, but rather can be estimated on the basis of a model. An alarm signal can then be utilized in various ways. An alarm signal of the evaluation unit is accompanied, for example, by a warning indicator in the region of the dashboard of a vehicle, it being possible for this warning indicator to be realized by a warning lamp. In this way, the driver of a vehicle is informed about the critical state of the battery and can initiate corresponding countermeasures. In the process, servicing personnel can be informed by means of fault codes for diagnosis purposes. The remedy for this fault mode would be to check the water level and state of the battery.

The model for estimating the water loss provides that the mass flow of the water loss on account of gas development in the battery is continuously estimated and is integrated with respect to the service life of the battery. In this case, the model uses, for example, the battery charging voltage and the battery temperature as input variables. In one embodiment, it is provided that at least the z-curve, which is used in the charging strategy of the battery, and the battery temperature are used in the model, and the mass flow of the water loss on account of gas development is determined as a function of the used z-curve and the battery temperature from a correlation, which is stored in the evaluation unit, at least between the mass flow of the water loss on account of gas development, a z-curve of the charging strategy and the battery temperature.

The z-curve of a charging strategy indicates the temperature-dependent setpoint voltage value which is designed to charge the battery up to a target state of charge. This target state of charge is often 100%. In this case, the z-curve of a battery defines equalization charging, wherein a setpoint voltage value which makes it easier to fully charge all cells in a rechargeable lead-acid battery is used for equalization charging. This is usually temperature-dependent and often defined in such a way that gas development under a maximum construction value lies in the middle of the defined temperature range. This z-curve of a battery can be obtained from the battery manufacturer or defined by the vehicle manufacturer in order to function well in a given target vehicle with a predicted use profile. The z-curve defines the voltage at the connection terminals of the battery in this case.

The correlation between said variables is stored, for example, in a one- or multi-dimensional reference table from which the evaluation unit can extract the mass flow of the water loss on account of gas development when various variables are known. If the charging strategy of the battery uses several z-curves and switches between these z-curves by a respective z-curve being activated, the respectively active z-curve of the charging strategy is used for estimating the water loss. Information relating to the respectively active z-curve can be derived from the charging strategy itself. If this information is not available, the respectively active z-curve of the charging strategy can also be determined by the battery charging voltage and the battery temperature being monitored, and it being determined which z-curve comes closest to the determined pair of measurement values comprising battery charging voltage and battery temperature. In this way, measured variables such as the battery charging voltage and the battery temperature are used to infer a probable z-curve which fits said measurement values.

Furthermore, it can be provided that the mass flow of the water loss on account of gas development is also stored in the reference table as a function of the state of charge (SOC) of the battery. In one embodiment, the correlation which is stored in the evaluation unit then indicates the mass flow of the water loss on account of gas development as a function of the state of charge of the battery, the active z-curve of the charging strategy of the battery and the battery temperature.

The battery temperature and the battery charging voltage can be determined, for example, using a conventional pole-niche sensor which serves as a battery monitoring sensor (BMS). The values which are measured in this way can be directly or indirectly transmitted to the evaluation unit by a sensor. Furthermore, the evaluation unit must not be an independent module, but rather its functionality can also be formed by interaction between a plurality of individual modules. The alarm signal which is generated by the evaluation unit can be processed in different ways in this case.

Certain embodiments are particularly suitable for reliably identifying excess water loss and therefore internal corrosion in lead-acid batteries (for example starter, lighting system, ignition) in motor vehicles. These symptoms indicate the end of the service life of the battery. However, these and other embodiments can also be extended to other applications, for example to monitoring lead-acid batteries in power supply systems of aircraft or watercraft.

Further advantages, special features and expedient developments can be found in the dependent claims and the following description of exemplary embodiments with reference to the drawings.

### BRIEF DESCRIPTION OF THE DRAWINGS

FIG. 1 shows the diagram of an algorithm in which the water loss is estimated on account of its integrated mass flow;

FIG. 2 shows the diagram of an algorithm in which method the state of charge of the battery is taken into account; and

FIG. 3 shows the diagram of an embodiment for monitoring a battery.

### DETAILED DESCRIPTION

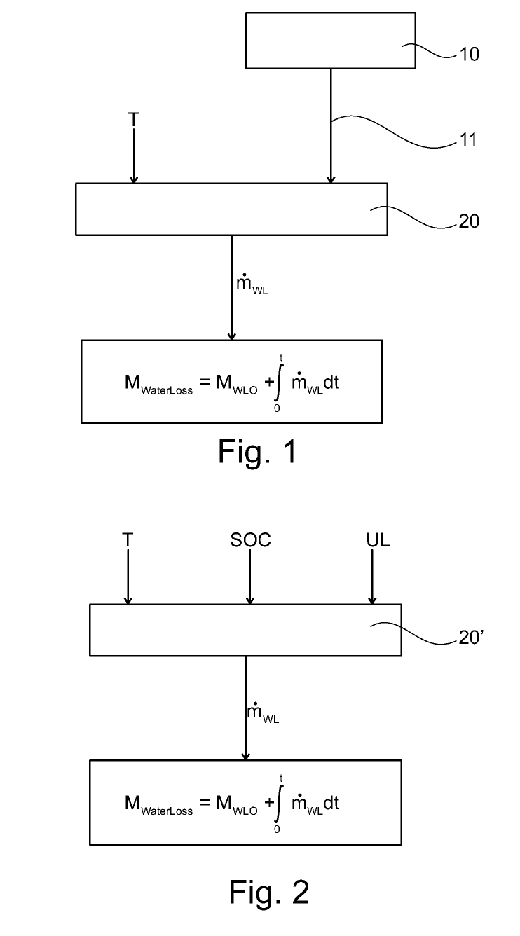

An algorithm which estimates the battery water loss M_{WaterLoss} on account of gas development or gas formation is shown in FIG. 1, wherein the algorithm can be used by an evaluation unit of the vehicle system. The algorithm assumes, for maximum accuracy, a high state of charge (SOC) of the battery and is used, in particular, in lead-acid batteries. The algorithm provides that the temperature-dependent mass flow of the water loss \dot{m}_{WL} is determined in a reference table 20 (look-up table) using the battery temperature \dot{T} and the active z-curve 11 of a charging strategy 10 of the battery. Said mass flow is integrated with respect to the service life of the battery.

In the case of a simple battery charging strategy with a single z-curve, the reference table 20, from which the temperature-dependent mass flow of the water loss \dot{m}_{WL} is determined, is one-dimensional (mass flow of the water loss: \dot{m}_{WL}(T)). If more than one z-curve is used and the charging strategy switches between said z-curves, it is assumed that the name of the respectively active z-curve or its index is supplied to the algorithm (mass flow of the water loss: \dot{m}_{WL}(T,ZCurve Index)).

If selection of the z-curve is not available to the algorithm on account of implementation restrictions, the active z-curve can also be determined by monitoring the battery charging voltage U_{L} and the battery temperature T. In the process, it is determined which z-curve corresponds most closely to these measurement values. As an alternative, the water loss rate can be determined for any possible charging voltage. Assuming that these water loss rates are determined using bench tests, the accuracy of the algorithm can be improved by measuring gas formation at various states of charge (SOC) and temperatures T and charging voltages U_{L} (see FIG. 2). In this case, the reference table 20 would be three-dimensional.

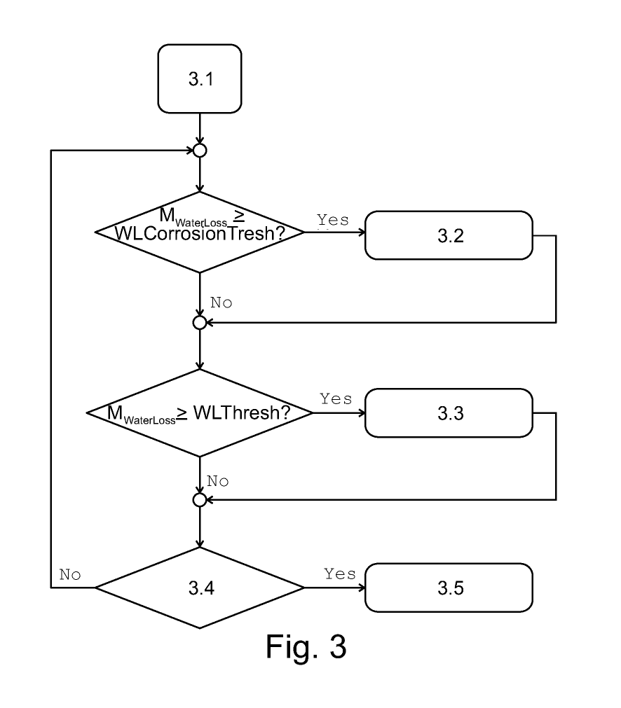

An exemplary algorithm for identifying high water loss rates and corrosion is illustrated in FIG. 3. If the power supply is started in step 3.1, the identification algorithm of the evaluation unit continuously compares the current prediction for the water loss M_{WaterLoss} with calibrated limit values WLThresh for the water loss and WLCorrosionThresh for the corrosion. If the predicted water loss M_{WaterLoss} exceeds the limit value WLCorrosionThresh, the corresponding indicator (flag) or the corresponding warning for internal corrosion is activated in step 3.2. If the predicted water loss M_{WaterLoss} exceeds the limit value WLThresh, the corresponding indicator (flag) or the corresponding warning for excessively high water loss and therefore low electrolyte is activated in step 3.3. In this case, the limit value can be different, depending on the battery construction. That is to say, the limit value for the water loss is usually lower, but does not have to be. As soon as the power supply is deactivated in step 3.4, the value of the water loss M_{WaterLoss} is stored as a new starting value M_{WLO} for the integration of the water loss in step 3.5.

What is claimed is:

1. A method for monitoring a state of a vehicle battery comprising:
by a processor,
obtaining, from data correlating water loss with battery temperature and a z-curve indicating a temperature dependent setpoint voltage at connection terminals of the battery, an estimated water loss of the battery, and
in response to the estimated water loss exceeding a threshold, outputting an alert.

2. The method of claim 1 further comprising obtaining the estimated water loss from data correlating the water loss with battery state of charge.

3. The method of claim 1 further comprising switching between a plurality of z-curves according to a charge strategy, wherein an active one of the plurality is the z-curve indicating a temperature dependent setpoint voltage at connection terminals of the battery.

4. The method of claim 3 further comprising identifying the active one based on a charge voltage for the battery and the temperature.

5. A system comprising:
an evaluation unit programmed to, in response to an estimated water loss of a battery exceeding a threshold, output an alert, wherein the estimated water loss is obtained by the evaluation unit from data correlating water loss with battery temperature and a z-curve indicating a temperature dependent setpoint voltage at connection terminals of the battery.

6. The system of claim 5, wherein the estimated water loss is further obtained by the evaluation unit from data correlating the water loss with battery state of charge.

7. The system of claim 5, wherein the evaluation unit is further programmed to switch between a plurality of z-curves according to a charge strategy, wherein an active one of the plurality is the z-curve indicating a temperature dependent setpoint voltage at connection terminals of the battery.

8. The system of claim 7, wherein the evaluation unit is further programmed to identify the active one based on a charge voltage for the battery and the temperature.

9. A method for monitoring the state of a vehicle battery comprising:
by a processor,
estimating water loss from the battery via a model, and
generating an alarm signal if the estimated water loss exceeds a defined limit value.

10. The method of claim 9, wherein the model provides that mass flow of the water loss is continuously estimated and is integrated with respect to service life of the battery.

11. The method of claim 10, wherein a z-curve indicating a temperature dependent setpoint voltage at connection terminals of the battery and a temperature of the battery are used in the model, and wherein the mass flow is based on the z-curve and the temperature.

12. The method of claim 11, wherein an active z-curve is used if a charging strategy for the battery has a plurality of z-curves.

13. The method of claim 12, wherein the active z-curve is identified by a charge voltage and the temperature.

14. The method of claim 11, wherein a state of charge of the battery is further used in the model, and wherein the mass flow is further based on the state of charge.
